(19) United States
(12) Patent Application Publication
(10) Pub. No.: US 2007/0272434 A1
(43) Pub. Date: Nov. 29, 2007

(54) PRINTED CIRCUIT BOARD AND MANUFACTURING METHOD THEREOF

(75) Inventors: Mitsuru HONJO, Osaka (JP); Hiroyuki HANAZONO, Osaka (JP)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: NITTO DENKO CORPORATION, Osaka (JP)

(21) Appl. No.: 11/751,054

(22) Filed: May 21, 2007

(30) Foreign Application Priority Data
May 26, 2006 (JP) 2006-146212

(51) Int. Cl. H05K 1/00

(52) U.S. Cl. 174/254

(57) ABSTRACT

A printed circuit board has a bending portion and a non-bending portion. A base insulating layer is provided over the bending portion and the non-bending portion. A plurality of conductor patterns are formed on the insulating layer. A cover insulating layer is formed on the insulating layer to cover the plurality of conductor patterns. A surface region of the plurality of conductor patterns in the bending portion is roughened.

### BACKGROUND OF THE INVENTION

1. Field of the Invention

The present invention relates to a printed circuit board for use in various kinds of electronic equipment and a manufacturing method thereof.

2. Description of the Background Art

A printed circuit board is generally produced by a semi-additive or subtractive method.

A printed circuit board produced by each of the above methods typically includes a base insulating layer for example of a polyimide film, a conductor pattern formed on the base insulating layer, and a cover insulating layer that covers the conductor pattern.

According to conventional techniques, in order to improve the adhesion between the conductor pattern and the cover insulating layer, the surface of the conductor pattern is subjected to roughening treatment (see for example JP 2001-36219 and 2).

The surface of the conductor pattern has irregularities by the roughening treatment. This causes an anchor effect, which improves the adhesion between the conductor pattern and the cover insulating layer.

In the circuit boards (printed circuit boards) disclosed by JP 2001-36219 A mentioned above and JP 2003-209351 A, however, almost the entire surface region of the conductor pattern that forms signal wirings is roughened. Consequently, when a high frequency signal (for example, 100 MHz or 300 MHz or higher) is transmitted through the conductor pattern of the circuit board, current is passed along the irregularities on the conductor pattern surface because of the conductor skin effect. Therefore, the substantial transmission path length increases, which deteriorates the transmission characteristic of the high frequency signal.

If for example the high frequency signal has a frequency of 1 GHz, the current is concentrated at a region about as deep as 2 μm from the surface of the conductor pattern. In this case, if the size of the irregularities on the conductor pattern after the roughening treatment is large, the substantial transmission path length increases, which considerably degrades the transmission characteristic.

If the cover insulating layer is formed without carrying out the roughening treatment to the conductor pattern, the adhesion between the conductor pattern and the cover insulating layer is not improved. Therefore, the conductor pattern and the cover insulating layer could be detached in a bending portion where the circuit board is repeatedly bent.

### SUMMARY OF THE INVENTION

An object of the invention is to provide a printed circuit board in which the adhesion between a wiring layer and a protecting layer is improved while the transmission characteristic is not deteriorated and a manufacturing method thereof.

(1)

According to one aspect of the invention, a printed circuit board having a bending portion that is bent at the time of use and a non-bending portion that is not bent at the time of use includes an insulating layer provided over the bending portion and the non-bending portion, a wiring layer formed on the insulating layer, and a protecting layer formed on the insulating layer to cover the wiring layer, in which a surface region of the wiring layer in the bending portion is roughened.

In the printed circuit board, the insulating layer is provided over the bending portion and the non-bending portion. The protecting portion is formed on the insulating layer to cover the wiring layer. The surface region of the wiring layer in the bending portion is roughened.

In this way, the entire region of the surface of the wiring layer in the bending portion and the non-bending portion is not roughened, and therefore the transmission characteristic of high frequency signals can be prevented from being deteriorated.

More specifically, only the surface region of the wiring layer in the bending portion is roughened, and therefore the substantial transmission path length can be prevented from being increased. Therefore, the transmission characteristic of high frequency signals is not deteriorated.

The surface region of the wiring layer in the bending portion is roughened, and therefore the adhesion between the wiring layer and the protecting layer can be improved. This prevents the detachment between the wiring layer and the protecting layer that could be caused by repetitive bending.

(2)

The roughened region may include a region on a surface on the opposite side to the interface between the wiring layer and the insulating layer. In this way, the adhesion between the wiring layer and the protecting layer can sufficiently be improved.

(3)

The arithmetic mean height of the roughened region may be larger than the arithmetic mean height of the other region that is not roughened.

In this way, the adhesion between the wiring layer and the protecting layer can sufficiently be secured by the roughened region while the transmission characteristic of high frequency signals can be prevented from being deteriorated by the other region that is not roughened.

(4)

The arithmetic mean height of the roughened region may be from 1 μm to 3 μm.

In this way, the transmission characteristic of high frequency signals can be prevented from being deteriorated while the adhesion between the wiring layer and the protecting layer can sufficiently be improved.

(5)

The wiring layer may have a plurality of wiring layers extending in parallel to one another in the bending portion and the surfaces of the plurality of wiring layers facing one another do not have to be roughened.

In this way, when current is passed along the surfaces of the plurality of wiring layers facing one another because of the proximity effect, the substantial transmission path length can be prevented from being increased. In this way, the adhesion between the plurality of wring layers and the protecting layer can be secured while the transmission characteristic of high frequency signals that could be adversely affected by increase in the substantial transmission path length can sufficiently be prevented from being deteriorated.

(6)

The arithmetic mean height of the surfaces of the plurality of wiring layers facing one another may be smaller than the arithmetic mean height of the roughened region.

In this way, when current is passed along the surfaces of the plurality of wiring layers facing one another because of the proximity effect, the substantial transmission path length can he prevented from being increased. In this way, the adhesion between the plurality of wring layers and the protecting layer can be secured while the transmission characteristic of high frequency signals that could be adversely affected by increase in the substantial transmission path length can sufficiently be prevented from being deteriorated.

(7)

According to another aspect of the invention, a method of manufacturing a printed circuit board having a bending portion that is bent at the time of use and a non-bending portion that is not bent at the time of use includes the steps of forming a wiring layer having a roughened surface region in the bending portion on an insulating layer provided over the bending portion and the non-bending portion and forming a protecting layer on the insulating layer to cover the wiring layer in the bending portion and the non-bending portion.

According to the method of manufacturing a printed circuit board, an insulating layer is provided over the bending portion and the non-bending portion. The wiring layer is formed on the insulating layer. The protecting layer is formed on the insulating layer to cover the wiring layer. The surface region of the wiring layer in the bending portion is roughened.

In this way, the entire region of the surface of the wiring layer in the bending portion and the non-bending portion is not roughened, and therefore the transmission characteristic of high frequency signals can be prevented from being deteriorated.

More specifically, only the surface region of the wiring layer in the bending portion is roughened, and therefore the substantial transmission path length can be prevented from being increased. In this way, the transmission characteristic of high frequency signals is not deteriorated.

The surface region of the wiring layer in the bending portion is roughened, and therefore the adhesion between the wiring layer and the protecting layer is improved. This prevents the detachment between the wiring layer and the protecting layer that could be caused by repetitive bending.

(8)

The step of forming the wiring layer may include the steps of forming a wiring layer on the insulating layer provided over the bending portion and the non-bending portion, forming resist for roughening in the surface region of the wiring layer excluding the bending portion, roughening the surface region of the wiring layer where the resist for roughening is not formed, and removing the resist for roughening.

In this case, the insulating layer is provided over the bending portion and the non-bending portion. Then, the resist for roughening is formed in the surface region of the wiring layer excluding the bending portion. The surface region of the wiring layer where the resist for roughening is not formed is then roughened. Thereafter, the resist for roughening is removed.

By these steps, the wiring layer having the roughened surface region in the bending portion is formed on the insulating layer provided over the bending portion and the non-bending portion.

(9)

The step of forming the wiring layer may include the steps of forming a wiring layer on the insulating layer provided over the bending portion and the non-bending portion, roughening a surface of the wiring layer, forming resist for smoothing in the surface region of the wiring layer excluding the non-bending portion, smoothing the surface region of the wiring layer where the resist for smoothing is not formed, and removing the resist for smoothing.

In this case, the wiring layer is formed on the insulating layer provided over the bending portion and the non-bending portion. Then, the surface of the wiring layer is roughened. Then, the resist for smoothing is formed on the surface region of the wiring layer excluding the non-bending portion. Then, the surface region of the wiring layer where the resist for smoothing is not formed is smoothed. Thereafter, the resist for smoothing is removed.

By these steps, the wiring layer having the roughened surface region in the bending portion is formed on the insulating layer provided over the bending portion and the non-bending portion.

(10)

The step of forming the wiring layer may include the steps of forming the wiring layer on the insulating layer provided over the bending portion and the non-bending portion using resist for plating in a pattern reversed from that of the wiring layer, forming resist for roughening on a surface region of the wiring layer in the non-bending portion and on the resist for plating, roughening the surface region of the wiring layer where the resist for roughening is not formed, and removing the resist for plating and the resist for roughening.

In this case, the wiring layer is formed on the insulating layer provided over the bending portion and the non-bending portion using the resist for plating in a pattern reversed from that of the wiring layer. Then, the resist for roughening is formed on the surface region of the wiring layer in the non-bending portion and on the resist for plating. Then, the surface region of the wiring layer where the resist for roughening is not formed is roughened. Thereafter, the resist for plating and the resist for roughening are removed.

By these steps, the wiring layer having the roughened surface region in the bending portion is formed on the insulating layer provided over the bending portion and the non-bending portion.

The wiring layer may have a plurality of wiring layers extending in parallel to one another in the bending portion and the surfaces of the plurality of the wiring layers facing one another do not have to be roughened.

According to the manufacturing method in particular, the surfaces of the wiring layers facing one another are not roughened. Therefore, when current is passed along the surfaces of the plurality of wiring layers facing one another because of the proximity effect, the substantial transmission path length can be prevented from being increased. In this way, the adhesion between the wiring layer and the protecting layer is secured while the transmission characteristic of high frequency signals that could be adversely affected by increase in the substantial transmission path length can sufficiently be prevented from being deteriorated.

(11)

The step of forming the wiring layer may include roughening a surface of a conductor layer in a layered board including an insulating layer and the conductor layer provided over the bending portion and the non-bending portion, forming a wiring layer on the insulating layer by forming resist for etching in a prescribed region of the surface of the conductor layer and etching the conductor layer excluding the prescribed region, removing the resist for etching, forming resist for smoothing in a surface region of the wiring layer in the bending portion, smoothing the surface region of the wiring layer where the resist for smoothing is not formed, and removing the resist for smoothing.

In this case, the surface of the conductor layer in the layered board including the insulating layer and the conductor layer provided over the bending portion and the non-bending portion is roughened. Then, the resist for etching is formed in a prescribed region of the surface of the conductor layer, and the conductor layer is etched excluding the prescribed region, so that the wiring layer is formed on the insulating layer. Then, the resist for etching is formed. The resist for smoothing is formed in the surface region of the wiring layer in the bending portion. Thereafter, the surface region of the wiring layer where the resist for smoothing is not formed is smoothed, and then the resist for smoothing is removed.

By these steps, the wiring layer having the roughed surface region in the bending portion is formed on the insulating layer provided over the bending portion and the non-bending portion.

According to the manufacturing method in particular, the surfaces of the plurality of wiring layers facing one another are not roughened. Therefore, when current is passed along the surfaces of the plurality of wiring layers facing one another because of the proximity effect, the substantial transmission path length can be prevented from being increased. In this way, the adhesion between the plurality of wiring layers and the protecting layer is secured while the transmission characteristic of high frequency signals that could be adversely affected by increase in the substantial transmission path length can sufficiently be prevented from being deteriorated.

(12)

The wiring layer may have a plurality of wiring layers extending in parallel to one another in the bending portion, and the step of forming the wiring layer may include roughening a surface region of the plurality of wiring layers in the bending portion excluding the surfaces of the wiring layers facing one another.

In this way, when current is passed along the surfaces of the plurality of wiring layers facing one another because of the proximity effect, the substantial transmission path length can be prevented from being increased. Therefore, the adhesion between the plurality of wiring layers and the protecting layer is secured while the transmission characteristic of high frequency signals that could be adversely affected by increase in the substantial transmission path length can sufficiently be prevented from being deteriorated.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a plan view of a general structure of each of printed circuit boards according to first to fourth embodiments of the invention;

FIG. 2 is a schematic sectional view showing steps in a method of manufacturing a printed circuit board according to a semi-additive method;

FIG. 3 is a sectional view showing steps until a printed circuit board is produced after a conductor pattern is formed on a base insulating layer;

FIG. 4 is a schematic view of a printed circuit board produced by a manufacturing method according to the first embodiment taken along line A-A in FIG. 1;

FIG. 5 is a sectional view of another example of steps until the printed circuit board is produced after the conductor pattern is formed on the base insulating layer;

FIG. 6 is a sectional view of yet another example of steps until the printed circuit board is produced after the step shown in FIG. 2(c); and

FIG. 7 is a sectional view showing steps until the printed circuit board according to the fourth embodiment is produced.

### DESCRIPTION OF THE PREFERRED EMBODIMENTS

Now, printed circuit boards according to embodiments of the invention will be described in conjunction with the accompanying drawings. Note that the printed circuit boards according to the embodiments are flexible printed circuit boards.

### (1) First Embodiment

To start with, a general structure of printed circuit boards according to the first embodiment and second to fourth embodiments that will be described will be described.

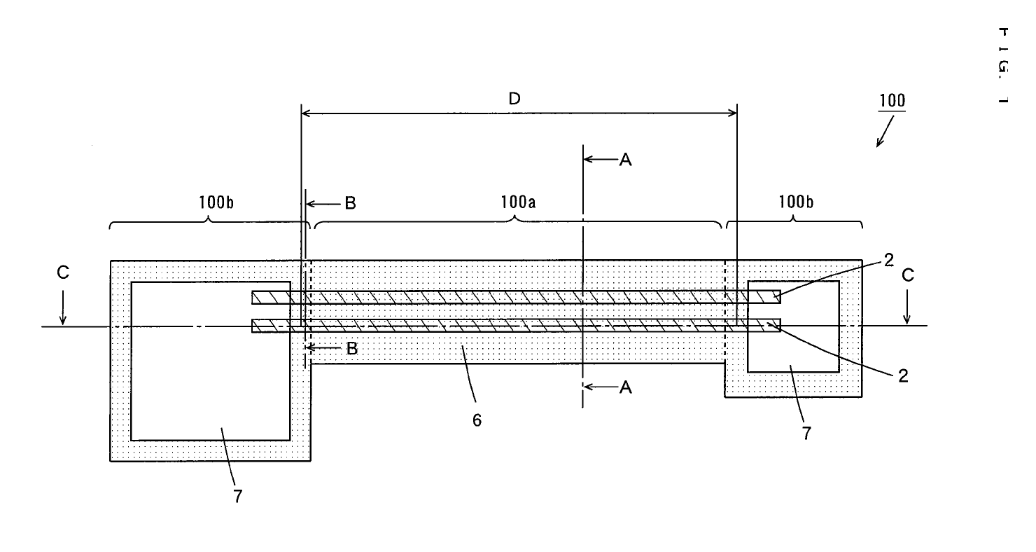

FIG. 1 is a plan view of a general structure of the printed circuit boards according to the first to fourth embodiments.

As shown in FIG. 1, the printed circuit board 100 according to the embodiment includes a bending portion 100a that is bent at the time of use and non-bending portions 100b that is not bent at the time of use. According to the embodiment, the bending portion 100a is provided between two non-bending portions 100b having different sizes.

The bending portion 100a is a part bent or repeatedly bent while the non-bending portions 100b are parts that are not bent where a semiconductor chip or the like is provided.

A plurality of (two in the embodiment) conductor patterns 2 are provided substantially parallel to the outer shape of the bending portion 100a between one non-bending portion 100b and another bending portion 100b. The cover insulating layer 6 is formed to cover the conductor patterns 2. The cover insulating layer 6 in each of the non-bending portions 100b is provided with a terminal opening 7 for a semiconductor chip or the like.

Both ends of the conductor patterns 2 are exposed at the terminal openings 7. The part of each conductor pattern 2 exposed at the terminal opening 7 serves as a terminal. The semiconductor chip or the like is connected to the terminal of the conductor pattern 2 in the terminal opening 7. As described above, the number of the conductor patterns 2 is two according to the embodiment, but the number is not limited to this and for example three or more patterns may be provided.

An electrolytic gold plating layer that is not shown is formed on the terminal of the conductor pattern 2. Note that the electrolytic gold plating layer may contain gold as a single constituent or may include gold as a main constituent and at least one element selected from the group consisting of copper (Cu), lead (Pb), silver (Ag), antimony (Sb), bismuth (Bi), indium (In), zinc (Zn), chromium (Cr), nickel (Ni), cobalt (Co), iron (Fe), molybdenum (Mo), germanium (Ge), garium (Ga), and phosphorus (P).

Now, a method of manufacturing the printed circuit board 100 according to the embodiment will be described in conjunction with the drawings showing the steps.

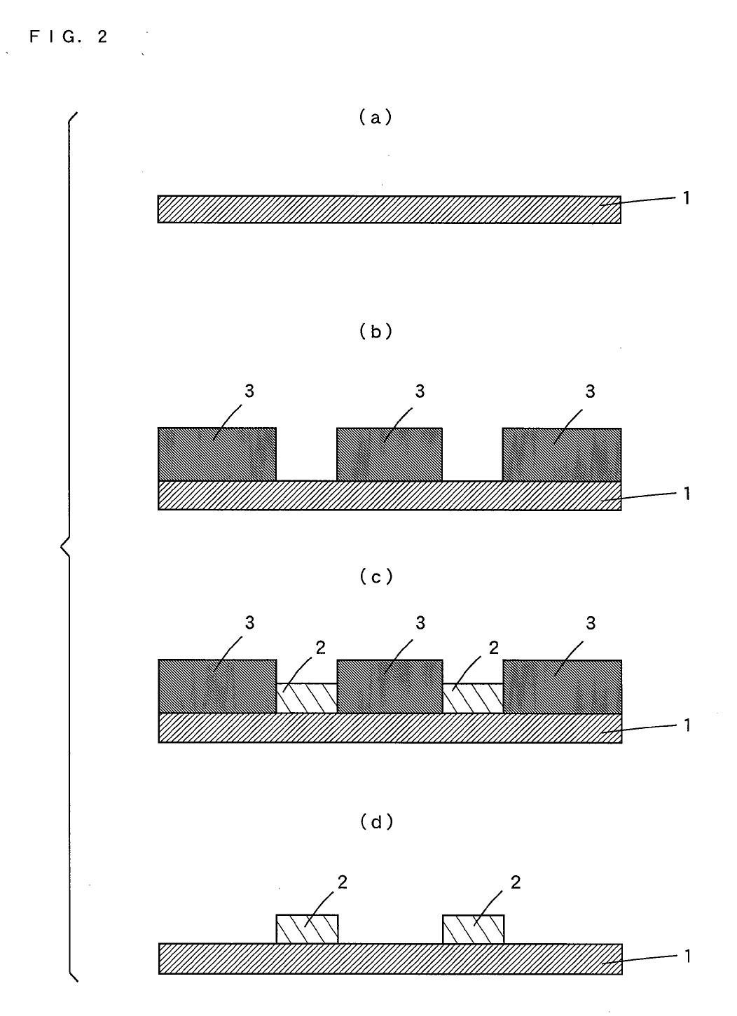

FIG. 2 is a schematic sectional view showing steps in the method of manufacturing the printed circuit board 100 according to a semi-additive method.

As shown in FIG. 2(a), a base insulating layer 1 for example of a polyimide film having a thickness of 12 μm is prepared.

Then, as shown in FIG. 2(b), plating resist 3 in a pattern reversed from that of a conductor pattern 2 to be formed in subsequent steps is formed on the base insulating layer 1 using dry film resist.

Then, as shown in FIG. 2(c), the conductor pattern 2 having a thickness of for example 18 μm is formed by electrolytic copper plating on the surface of the base insulating layer 1 where the plating resist 3 is not formed.

Then, as shown in FIG. 2(d), the plating resist 3 is removed by peeling or the like. If there is a concern about the adhesion between the base insulating layer 1 and the conductor pattern 2, a thin metal film may be provided between the base insulating layer 1 and the conductor pattern 2 so that the adhesion may be improved.

Now, steps until the printed circuit board 100 according to the embodiment is formed after the above step shown in FIG. 2(d) will be described.

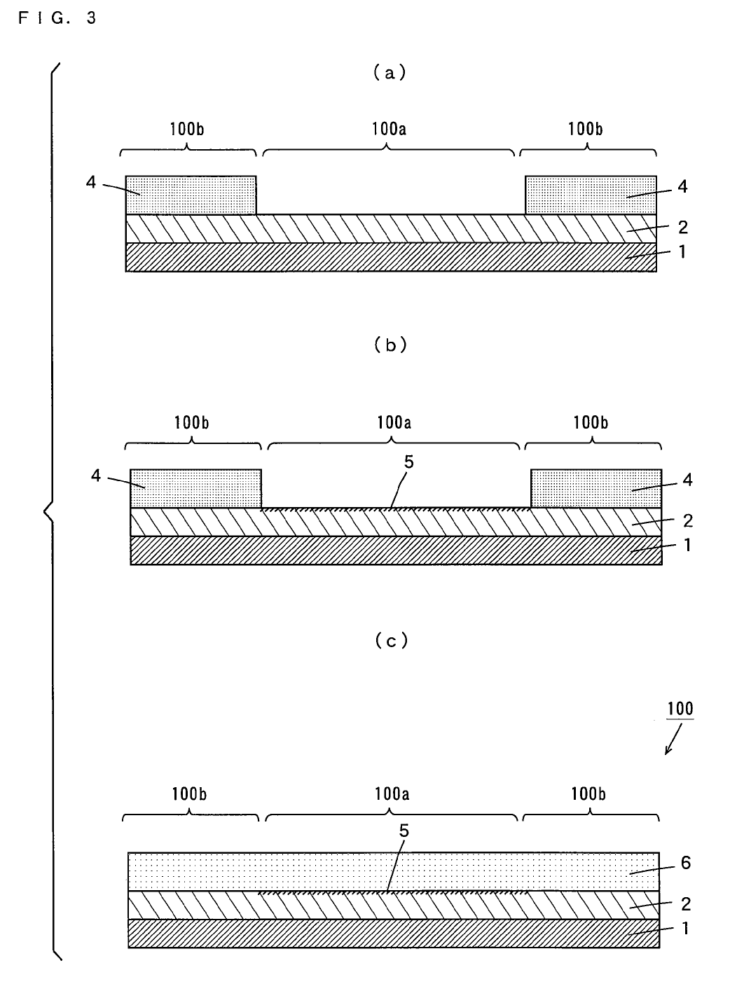

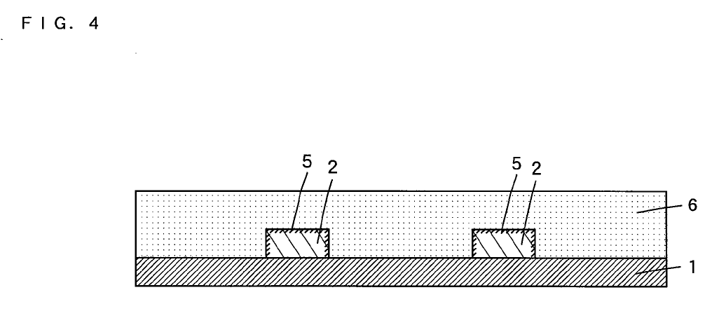

FIG. 3 is a sectional view showing the steps until the printed circuit board 100 is produced after the conductor pattern 2 is formed on the base insulating layer 1. Note that in FIG. 3, the D region in the section of the printed circuit board 100 taken along line C-C in FIG. 1 is shown.

As shown in FIG. 3(a), a prescribed conductor pattern 2 is formed on the base insulating layer 1 over the bending portion 100a and the two non-bending portions 100b.

Roughening resist 4 of photo-sensitive resin is formed on the conductor pattern 2 in the two non-bending portions 100b. More specifically, since the upper surface of the conductor pattern 2 in the bending portion 100a is subjected to roughening as will be described, the roughening resist 4 is not formed on the conductor pattern 2 in the bending portion 100a. Details of the roughening treatment will be described later.

Then, with reference to FIG. 3(a), the conductor pattern 2 in the two non-bending portions 100b and the roughening resist 4 provided thereon are immersed in a treatment liquid for the roughening treatment. As shown in FIG. 3(b), by the process, a roughened portion 5 having for example irregularities is formed on the surface of the conductor pattern 2 in the bending portion 100a where the roughening resist 4 is not formed.

As the treatment liquid for the roughening treatment, a liquid mixture of sulfuric acid and hydrogen peroxide, an alkali chlorous acid-based treatment liquid, or an organic acid-based treatment liquid may be used.

Examples of the liquid mixture of sulfuric acid and hydrogen peroxide may include MECBRITE™ (CB-5004) and MEC V-Bond™ (B0-7770) from MEC CO., LTD., and ME-605 and MultiBond™ (MB-100) from Macdermid Inc.

Examples of the alkali chlorcus acid-based treatment liquid may include Omnibond™ (omnibond 9251) and B0-2000 from Macdarmid Inc. An example of the organic acid-based treatment liquid may include MECetchBOND™ (CZ-8100) from MEC CO., LTD.

The surface roughness (arithmetic mean height) Ra of the roughened portion 5 is preferably from 1 μm to 3 μm. According to the embodiment, the surface roughness (arithmetic mean height) Ra of the roughened portion 5 may be for example 2 μm. Note that surface roughness (arithmetic mean height) Ra is a parameter that represents a surface roughness defined by Japan Industrial Standards (JIS B 0601-1994) and measured for example using a probe sensing surface roughness tester. The surface roughness (arithmetic mean height) Ra in the region of the conductor pattern 2 excluding the roughened portion 5 is smaller than the surface roughness (arithmetic mean height) Ra of the roughened portion 5.

Then, as shown in FIG. 3(c), the roughening resist 4 is removed for example by peeling. A cover insulating layer 6 for example of polyimide is formed on the base insulating layer 1 and the conductor pattern 2 excluding the region of the terminal openings 7 (FIG. 1) on the conductor pattern 2. In this way, a part of the cover insulating layer 6 is bonded to the roughened portion 5 formed on the surface of the conductor pattern 2 in the bending portion 100a. In FIG. 3, the cover insulating layer 6 formed on the insulating layer 1 is not shown because of the position of the section line. In this way, the printed circuit board 100 is formed in which the conductor pattern 2 and the cover insulating layer 6 in the bending portion 100a are bonded through the roughened portion 5.

A schematic sectional view of the printed circuit board 100 produced in this manner taken along line A-A (in FIG. 1) will be described.

FIG. 4 is the schematic sectional view of the printed circuit board 100 produced according to the method of manufacturing the printed circuit board 100 according to the first embodiment taken along line A-A (in FIG. 1).

As described above, according to the embodiment, the base insulating layer 1 and the conductor pattern 2 thereon without the roughening resist 4 on the conductor pattern 2 in the bending portion 100a are immersed in a treatment liquid for the roughening treatment.

In this way, as shown in FIG. 4, at the conductor pattern 2 in the bending portion 100a, the roughened portion 5 is formed on the surface of the conductor pattern 2 excluding the adhesion surface (which is the lower surface in FIG. 4) with the base insulating layer 1 (which corresponds to the upper surface and both side surfaces in FIG. 4).

### (2) Second Embodiment

Now, a method of manufacturing a printed circuit board 100 according to the second embodiment will be described.

According to the second embodiment, the steps until a prescribed conductor pattern 2 is formed on a base insulating layer 1 by a semi-additive method are the same as those of the first embodiment (that correspond to FIGS. 2(a) to (d)) and therefore the description about the steps is not repeated.

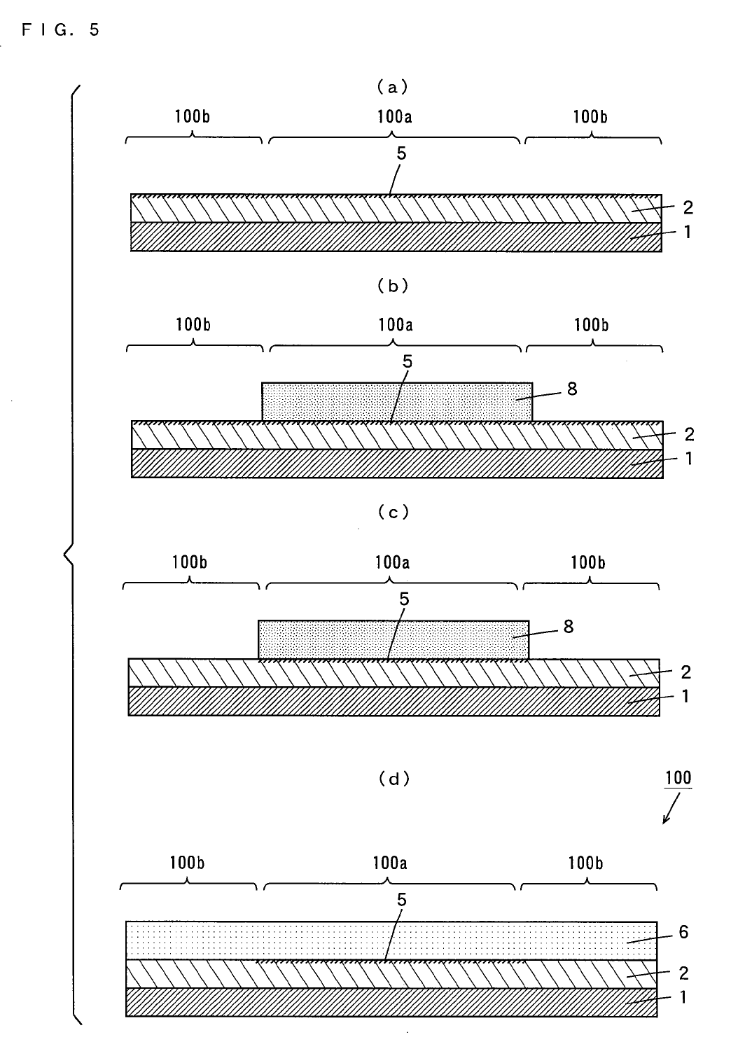

FIG. 5 includes sectional views of another example of steps until the printed circuit board 100 is produced after the conductor pattern 2 is formed on the base insulating layer 1. Note that FIG. 5 shows the D region of the printed circuit board 100 taken along line C-C in FIG. 1.

The prescribed conductor pattern 2 is formed on the base insulating layer 1 over the bending portion 100a and the two non-bending portions 100. In this way, the base insulating layer 1 and the conductor pattern 2 formed thereon are immersed in the same treatment liquid for roughening as that of the first embodiment.

By this process, as shown in FIG. 5(a), roughened portions 5 are formed on the surface of the conductor pattern 2 over the bending portion 100a and the two non-bending portions 100b. The surface roughness (arithmetic mean height) Ra of the roughened portion 5 may be for example 2 μm.

Then, as shown in FIG. 5(b), smoothing resist 8 is formed on the conductor pattern 2 in the bending portion 100a. This is for leaving the roughened portion 5 formed on the conductor pattern 2 in the bending part 100a as will be described.

Then, as shown in FIG. 5(c), the conductor pattern 2 and the smoothing resist 8 formed thereon in the bending portion 100a are immersed in a treatment liquid for smoothing. In this way, the roughened portions 5 formed on the conductor pattern 2 in the two non-bending portions 100b are smoothed.

According to the embodiment, examples of the treatment liquid for the smoothing may include an aqueous solution of sodium persulfate, an aqueous solution of ammonium persulfate, and an aqueous solution of potassium persulfate.

Then, as shown in FIG. 5(d), the smoothing resist 8 is removed by peeling or the like. A cover insulating layer 6 is formed on the base insulating layer 1 and the conductor pattern 2 excluding the region of the terminal openings 7 (FIG. 1) on the conductor pattern 2. In this way, a part of the cover insulating layer 6 is bonded to the roughened portion 5 formed at the surface of the conductor pattern 2 in the bending portion 100a. In FIG. 5, the cover insulating layer 6 formed on the base insulating layer 1 is not shown because of the position of the section line. In this way, the printed circuit board 100 is produced in which the conductor pattern 2 and the cover insulating layer 6 in the bending portion 100a are bonded through the roughened portion 5.

Note that a schematic view of the printed circuit board 100 produced in this way taken along line A-A (in FIG. 1) is the same as that shown in FIG. 4.

### (3) Third Embodiment

Now, a method of manufacturing a printed circuit board 100 according to the third embodiment will be described.

The steps until plating resist 3 is formed on a base insulating layer 1 and then a conductor pattern 2 is formed on the surface of the base insulating layer 1 where the plating resist 3 is not formed are the same as those of the first embodiment (that correspond to FIGS. 2(a) to (c)) and therefore the description about the steps is not repeated. Therefore, in the following paragraphs, steps until the printed circuit board 100 is produced after the above step in FIG. 2(c) will be described.

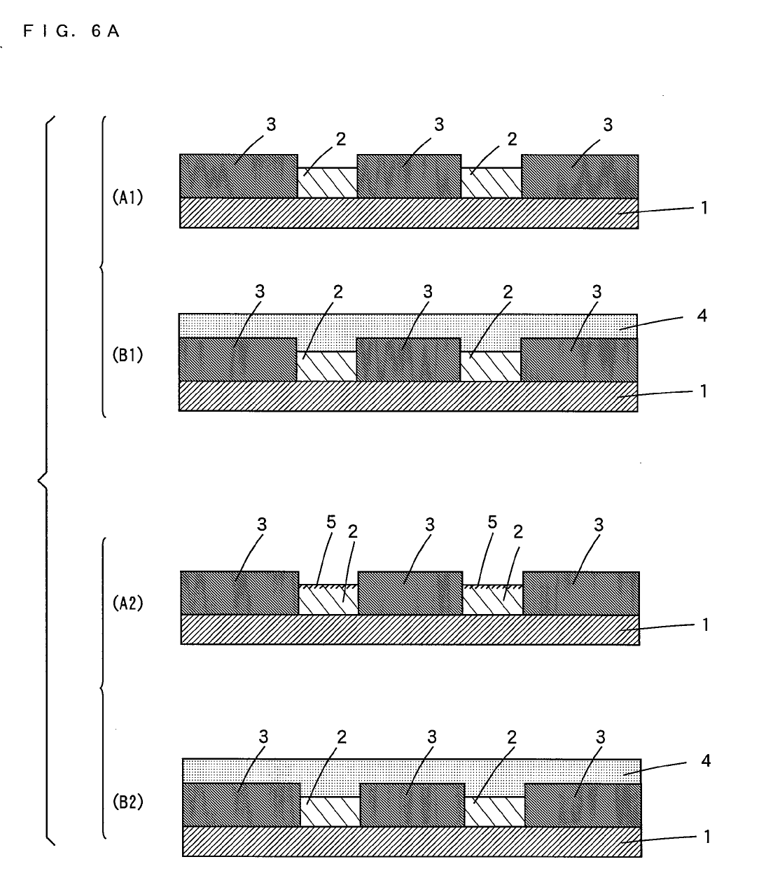

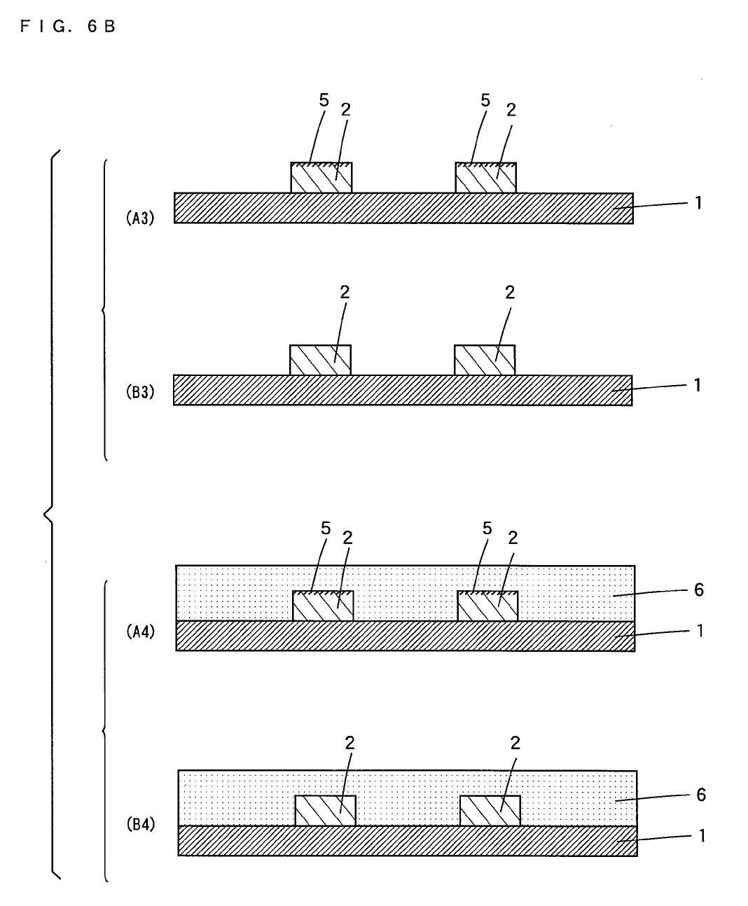

FIGS. 6A and 6B are sectional views showing yet another example of steps until the printed circuit board 100 is produced after the step in FIG. 2(c).

In FIGS. 6A and 6B, (A1) and (B1), (A2) and (B2), (A3) and (B3), and (A4) and (B4) are sectional views of different regions in the same steps.

More specifically, (A1), (A2), (A3), and (A4) each show a sectional view taken along line A-A in the bending portion 100a of the printed circuit board 100 in FIG. 1, and (B1), (B2), (B3), and (B4) each show a sectional view taken along line B-B in one of the non-bending portion 100b in the printed circuit board 100 taken along line B-B. Note that in the following paragraphs, the section in one of the non-bending portions 100b will be described with reference to sectional views taken along line B-B while the other non-bending portion 100b has the same sectional structure and therefore the description is not repeated.

As shown in FIG. 6A (A1), in the bending portion 100a, the state after the process in the step in FIG. 2(c) is maintained.

Meanwhile, as shown in FIG. 6A (B1), in the non-bending portion 100b, roughening resist 4 is formed on the conductor pattern 2 and the plating resist 3 after the process in the step in FIG. 2(c).

Then, as shown in FIG. 6A (A2), in the bending portion 100a, the base insulating layer 1 with the conductor pattern 2 and the plating resist 3 formed thereon is immersed in the same treatment liquid as that of the first embodiment. In this way, a roughened portion 5 is formed on the surface of the conductor pattern 2. Note that the side surfaces of the conductor pattern 2 are in contact with the side surfaces of the plating resist 3, and therefore the roughened portion 5 is not formed at the side surfaces of the conductor pattern 2. The surface roughness (arithmetic mean height) Ra of the roughened portion 5 is for example 2 μm.

Meanwhile, as shown in FIG. 6A (B2), in the non-bending portion 100b, the state after the process in the step in FIG. 6A (B1) is maintained.

Then, as shown in FIG. 6B (A3), in the bending portion 100a, the plating resist 3 is removed.

As shown in FIG. 6B (B3), in the non-bending portion 100b, the plating resist 3 and the roughening resist 4 are both removed.

Then, as shown in FIG. 6B (A4), in the bending portion 100a, a cover insulating layer 6 is formed on the base insulating layer 1 and the conductor pattern 2 provided with the roughened portion 5 thereon.

Meanwhile, as shown in FIG. 6B (B4), in the non-bending portion 100b, the cover insulating layer 6 is formed on the base insulating layer 1 and the conductor pattern 2 on which the roughened portion 5 is not formed thereon.

In this way, the printed circuit board 100 in which the conductor pattern 2 and the cover insulating layer 6 in the bending portion 100a are bonded through the roughened portion 5 is produced.

### (4) Fourth Embodiment

Now, a method of manufacturing a printed circuit board 100 according to the fourth embodiment will be described.

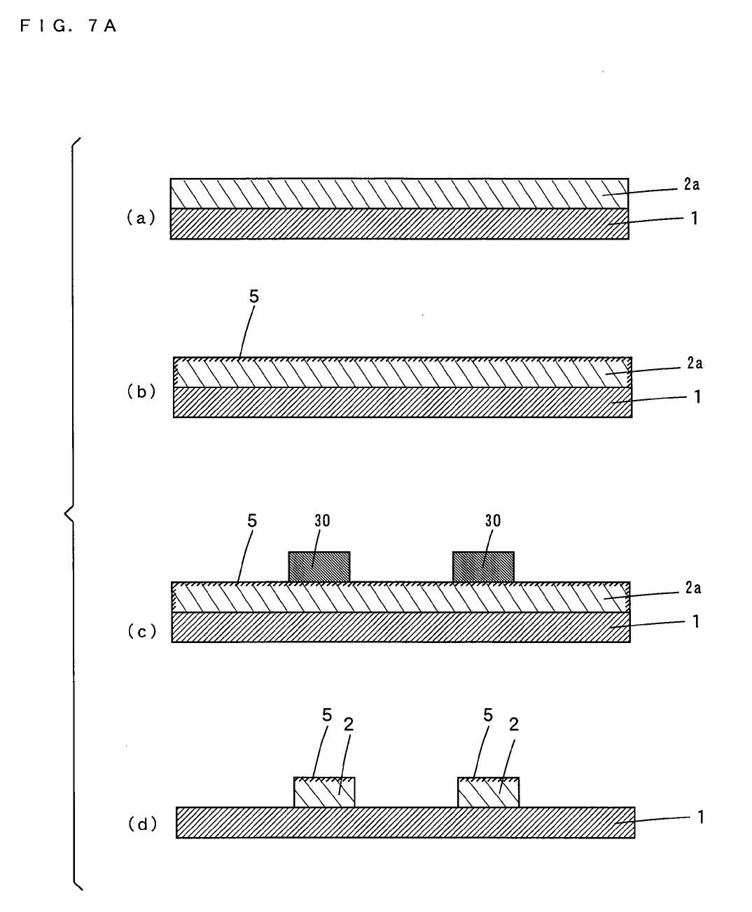

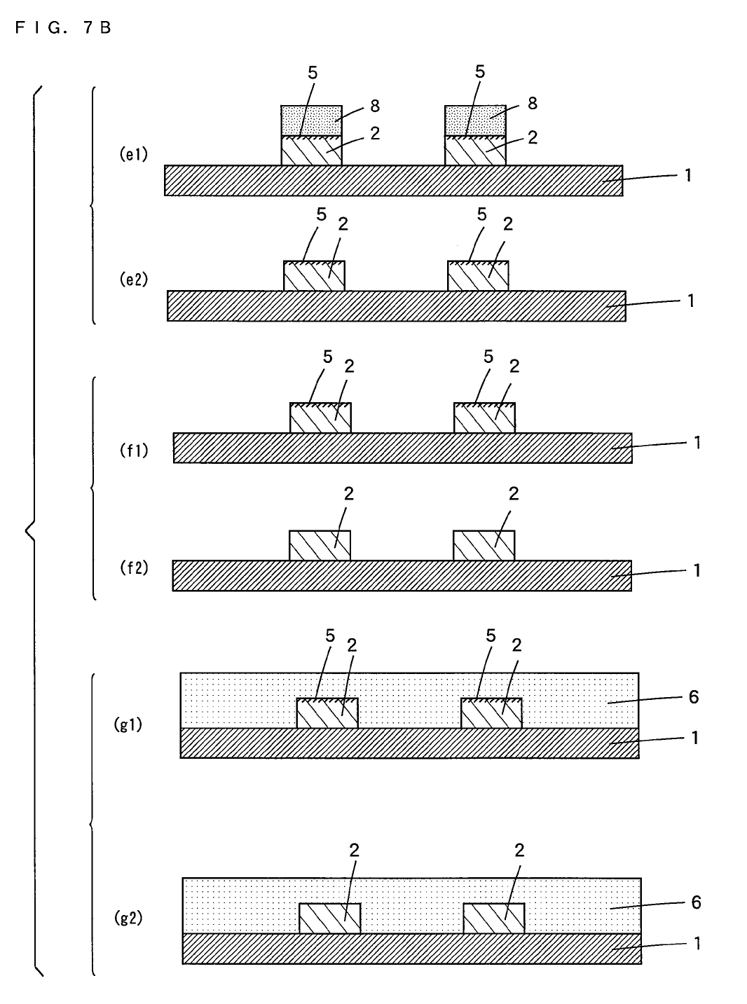

FIGS. 7A and 7B are sectional views showing steps until the printed circuit board 100 according to the fourth embodiment is produced.

In FIG. 7B, (e1) and (e2), (f1) and (f2), and (g1) and (g2) are sectional views of different regions in the same steps.

More specifically, (e1), (f1), and (g1) are sectional view of the printed circuit board 100 in the bending portion 100a in FIG. 1 taken along line A-A, and (e2), (f2), and (g2) are sectional views of the printed circuit board 100 in one of the non-bending portions 100b in FIG. 1 taken along line B-B.

In FIGS. 7A(a) to (d), the sectional view of the printed circuit board 100 in the bending portion 100a taken along line A-A and the sectional view in the non-bending portion 100b taken along line B-B are the same, and therefore only one sectional view is shown. Hereinafter, the structure of the section of one of the non-bending portions 100b will be described with reference to the sectional view taken along line B-B while the other non-bending portion 100b has the same sectional structure and therefore the description is not provided.

As shown in FIG. 7A (a), a two-layer base material having a layered structure including a base insulating layer 1 for example of a polyimide film having a thickness of for example 12 μm and a conductor layer 2a for example of a copper foil on the base insulating layer 1 is prepared.

Then, as shown in FIG. 7A (b), the two-layer base material is immersed in the same treatment liquid for roughening (for example at 32° C.) as that of the first embodiment for one minute. In this way, the roughened portion 5 is formed on the surface of the conductor layer 2a (the upper and both side surfaces) excluding the adhesion surface (the lower surface in FIG. 7A) with the base insulating layer 1. Note that the surface roughness (arithmetic mean height) Ra of the roughened portion 5 is for example 2 μm.

Then, in order to etch the conductor layer 2a and form a prescribed conductor pattern 2 that will be described, etching resist 30 is formed in the region on the conductor layer 2a excluding the region to be etched as shown in FIG. 7A (c).

After the etching using a prescribed etchant, the etching resist 30 is removed, so that the conductor pattern 2 is formed on the base insulating layer 1 as shown in FIG. 7A (d). Note that the roughened portion 5 is formed on the surface of the formed conductor pattern 2.

Then, as shown in FIG. 7B (e1), smoothing resist 8 of photosensitive resin is formed on the conductor pattern 2 in the bending portion 100a.

As shown in FIG. 7B (e2), in the non-bending portion 100b, the state after the process in the step in FIG. 7A (d) is maintained.

The conductor pattern 2 and the smoothing resist 8 formed thereon in the bending portion 100a are immersed in the same treatment liquid for smoothing as that of the second embodiment. Then, the smoothing resist 8 is removed.

In this way, as shown in FIG. 7B (f1), the roughened portion 5 on the conductor pattern 2 is maintained in the bending portion 100a. Meanwhile, as shown in FIG. 7B (f2), the roughened portion 5 on the conductor pattern 2 in the non-bending portion 100b is smoothed and removed.

Then, as shown in FIG. 7B (g1), in the bending portion 100a, a cover insulating layer 6 is formed on the base insulating layer 1 and the conductor pattern 2 having the roughened portion 5 formed thereon.

Meanwhile, as shown in FIG. 7B (g2), the cover insulating layer 6 is formed on the base insulating layer 1 and the conductor pattern 2 where the roughened portion 5 is not formed in the non-bending portion 100b.

In this manner, the printed circuit board 100 in which the conductor pattern 2 and the cover insulating layer 6 in the bending portion 100a are bonded through the roughened portion 5 is produced.

### (5) Other Embodiments

In any of the above-described embodiments, the semi-additive method is employed as a method of manufacturing the printed circuit board 100 while the method is not limited to this and any other methods such as subtractive and full additive methods may be employed.

Furthermore, the terminal opening 7 in the non-bending portion 100b in the printed circuit board 100 may be connected with a semiconductor chip or any other printed circuit board.

Other examples of the material of the base insulating layer 1 may include engineering plastic films such as a polyparabanic acid film, a polyester film, a polyethylene naphthalate film, a polyether sulfone film, a polyether imide film, and a polyether ether ketone film.

Other examples of the material of the cover insulating layer 6 may include engineering plastic films such as a polyparabanic acid film, a polyester film, a polyethylene naphthalate film, a polyether sulfone film, a polyether imide film, and a polyether ether ketone film. The material of the cover insulating layer 6 may be the same as or different from the material of the base insulating layer 1.

The material of the conductor pattern 2 is not limited to copper and any other metal material such as a copper-containing alloy, aluminum, and silver may be used.

### (6) Effects in the Above Described Embodiments

In the above described embodiments, the roughened portion 5 is formed on the conductor pattern 2 in the bending portion 100a of the printed circuit board 100 by the roughening treatment. The cover insulating layer 6 is bonded through the roughened portion 5 formed on the conductor pattern 2.

In this structure, the deterioration of the transmission characteristic of high frequency signals (such as at 100 MHz or higher or 300 MHz or higher) caused by roughening the region on the conductor pattern 2 in the bending portion 100a and the non-bending portions 100b can be prevented.

More specifically, by forming the roughened portion 5 only in the region on the conductor pattern 2 in the bending portion 100a, the substantial transmission path length can be prevented from being increased. In this way, the transmission characteristic of high frequency signals is not deteriorated.

By forming the roughened portion 5 on the conductor pattern 2 in the bending portion 100a, the adhesion between the conductor pattern 2 and the cover insulating layer 6 can be improved. In this way, the conductor pattern 2 and the cover insulating layer 6 can be prevented from being detached by bending or repetition of bending.

In the printed circuit boards 100 according to the first and second embodiments in particular, the roughened portion 5 is formed on the surface of the conductor pattern 2 in the bending portion 100a excluding the adhesion surface with the insulating layer 1. This improves the adhesion between the conductor pattern 2 and the cover insulating layer 6.

In the printed circuit boards 100 according to the third and fourth embodiments in particular, the roughened portion 5 is formed on the upper surface of the conductor pattern 2 in the bending portion 100a. In this way, the substantial transmission path length can further be prevented from being increased. Therefore, the transmission characteristic of high frequency signals can further be prevented from being deteriorated.

The following effects are also brought about in the printed circuit boards 100 according to the third and fourth embodiments.

More specifically, when current is passed through adjacent conductor patterns 2 in opposite directions from one another, the current can be passed along the side surface of each of the conductor patterns 2 (the proximity effect). Therefore, the roughened portion 5 is formed on the upper surface of the conductor pattern 2 in the bending portion 100a as described above, so that the substantial transmission path length can sufficiently be prevented from being increased. In this way, the transmission characteristic of high frequency signals can sufficiently be prevented from being deteriorated.

### (7) Correspondences between Various Elements in Claims and Elements in Various Embodiments

In the following paragraphs, non-limiting examples of correspondences between various elements recited in the claims below and those described above with various preferred embodiments of the present invention are explained.

In the embodiments described above, the base insulating layer 1 is an example of the insulating layer, the conductor pattern 2 is an example of the wiring layer, and the cover insulating layer 6 is an example of the protecting layer. The roughening resist 4 is an example of the resist for roughening, the smoothing resist 8 is an example of the resist for smoothing, the plating resist 3 is an example of the resist for plating, and the etching resist 30 is an example of the resist for etching.

### EXAMPLES

Now, inventive examples and comparative examples will be described.

### (a) Inventive Example 1

A printed circuit board 100 was produced according to the first embodiment described above. Note that in the following paragraphs, parts in common with those of the first embodiments are not described except for a specific design condition.

As the specific design condition, the thickness of the base insulating layer 1 was 12 μm, and the thickness of the conductor pattern 2 was 18 μm.

In the roughening treatment, MacDermid MultiBond™ (MB-100) was used as a treatment liquid at 32° C. for immersion for one minute. The surface roughness (arithmetic mean height) Ra of the roughened portion 5 was 2 μm.

### (b) Inventive Example 2

A printed circuit board 100 was produced according to the second embodiment described above. Note that in the following paragraphs, parts in common with that of the second embodiment are not described except for a specific design condition.

As the specific design condition, the thickness of the base insulating layer 1 was 12 μm, and the thickness of the conductor pattern 2 was 18 μm.

In the roughening treatment, the same treatment liquid as that of Inventive Example 1 as described above was used and the surface roughness (arithmetic means height) Ra of the roughened portion 5 was 2 μm.

In the smoothing treatment, an aqueous solution of sodium persulfate was used as a treatment liquid.

### (c) Inventive Example 3

A printed circuit board 100 was produced according to the third embodiment described above. Note that in the following paragraphs, parts in common with those of the third embodiment are not described except for a specific design condition.

As the specific design condition, the thickness of the base insulating layer 1 was 12 μm, and the thickness of the conductor pattern 2 was 18 μm.

In the roughening treatment, the same treatment liquid as that of Inventive Example 1 described above was used and the surface roughness (arithmetic means height) Ra of the roughened portion 5 was 2 μm.

### (d) Inventive Example 4

A printed circuit board 100 was produced according to the fourth embodiment described above. Note that in the following paragraphs, parts in common with those of the fourth embodiment are not described except for a specific design condition.

As the specific design condition, the thickness of the base insulating layer 1 was 12 μm, and the thickness of the conductor pattern 2a of a copper foil was 20 μm.

The roughening treatment was carried out in the same manner as Inventive Example 1 and the same treatment liquid as that of Inventive Example 1 was used. The surface roughness (arithmetic mean height) Ra of the roughed portion 5 was 2 μm. In the smoothing treatment, the same treatment liquid as that of Inventive Example 2 described above was used.

### (e) Comparative Example 1

Except that the roughening treatment was not carried out, a printed circuit board was produced in the same manner as that of Inventive Example 1.

More specifically, the roughened portion 5 was not formed on the surface of the conductor pattern 2 formed on the base insulating layer 1, and therefore the entire surface of the conductor pattern 2 in the bending portion 100a and the non-bending portions 100b was smooth. Note that the surface roughness (arithmetic mean height) Ra of the conductor pattern 2 was less than 1.0 μm.

### (f) Comparative Example 2

Except that the smoothing treatment was not carried out, a printed circuit board was produced in the same manner as that of Inventive Example 2.

More specifically, in this comparative example, the roughened portion 5 was formed on the entire surface of the conductor pattern 2 in the bending portion 100a and the non-bending portions 100b. The surface roughness (arithmetic mean height) Ra of the roughened portion was 2 μm.

(g) Evaluation

The printed circuit boards 100 produced according to Inventive Examples 1 to 4 and the printed circuit boards produced according to Comparative Examples 1 and 2 were tested for their bending reliability. Note that in the bending reliability test, a printed circuit board is repeatedly bent (bending operation) and then it is examined whether the conductor pattern 2 and the cover insulating layer 6 are detached from each other.

As a result, in the bending portions 100a in each of the printed circuit boards 100 according to Inventive Examples 1 to 4 and the printed circuit board according to Comparative Example 2, there was no detachment between the conductor pattern 2 and the cover insulating layer 6. In the bending portion 100a of the printed circuit board according to Comparative Example 1, however, the conductor pattern 2 and the cover insulating layer 6 were detached from each other.

In the printed circuit boards 100 according to Inventive Examples 1 to 4 and the printed circuit board according to Comparative Example 1, the transmission loss at 1 GHz as a high frequency characteristic was 0.1 dB/cm while in the printed circuit board according to Comparative Example 2, the transmission loss at 1 GHz as a high frequency characteristic was 0.5 dB/cm, which was a considerable deterioration.

It was confirmed from the above described result that by forming the roughened portion 5 only in the region on the conductor pattern 2 in the bending portion 100a, the substantial transmission path length was prevented from being increased and therefore the transmission characteristic of high frequency signals was not deteriorated.

It was also confirmed that by forming the roughened portion 5 on the conductor pattern 2 in the bending portion 100a, the adhesion between the conductor pattern 2 and the cover insulating layer 6 could be improved.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A printed circuit board having a bending portion that is bent at the time of use and a non-bending portion that is not bent at the time of use, comprising:
an insulating layer provided over said bending portion and said non-bending portion;
a wiring layer formed on said insulating layer; and
a protecting layer formed on said insulating layer to cover said wiring layer,
a surface region of said wiring layer in said bending portion being roughened.

2. The printed circuit board according to claim 1, wherein said roughened region includes a region on a surface on the opposite side to the interface between said wiring layer and said insulating layer.

3. The printed circuit board according to claim 1, wherein the arithmetic mean height of said roughened region is larger than the arithmetic mean height of the other region that is not roughened.

4. The printed circuit board according to claim 3, wherein the arithmetic mean height of said roughened region is from 1 μm to 3 μm.

5. The printed circuit board according to claim 1, wherein said wiring layer has a plurality of wiring layers extending in parallel to one another in said bending portion and the surfaces of said plurality of wiring layers facing one another are not roughened.

6. The printed circuit board according to claim 5, wherein the arithmetic mean height of said surfaces of said plurality of wiring layers facing one another is smaller than the arithmetic mean height of said roughened region.

7. A method of manufacturing a printed circuit board having a bending portion that is bent at the time of use and a non-bending portion that is not bent at the time of use, comprising the steps of:
forming a wiring layer on an insulating layer provided over said bending portion and said non-bending portion, said wiring layer having a surface region in said bending portion being roughened; and
forming a protecting layer on said insulating layer to cover said wiring layer in said bending portion and said non-bending portion.

8. The method of manufacturing a printed circuit board according to claim 7, wherein said step of forming said wiring layer includes the steps of
forming one or more wiring layers on the insulating layer provided over said bending portion and said non-bending portion,
forming resist for roughening in the surface region of said wiring layer excluding said bending portion,
roughening the surface region of said wiring layer where said roughening resist is not formed, and
removing said resist for roughening.

9. The method of manufacturing a printed circuit board according to claim 7, wherein said step of forming said wiring layer includes the steps of
forming a wiring layer on the insulating layer provided over said bending portion and said non-bending portion,
roughening a surface of said wiring layer,
forming resist for smoothing in the surface region of said wiring layer excluding said non-bending portion,
smoothing the surface region of said wiring layer where said resist for smoothing is not formed, and
removing said resist for smoothing.

10. The method of manufacturing a printed circuit board according to claim 7, wherein said step of forming said wiring layer includes the steps of
forming said wiring layer on the insulating layer provided over said bending portion and said non-bending portion using resist for plating in a pattern reversed from that of said wiring layer,
forming resist for roughening on a surface region of said wiring layer in said non-bending portion and on said resist for plating,
roughening the surface region of said wiring layer where said resist for roughening is not formed, and
removing said resist for plating and said resist for roughening.

11. The method of manufacturing a printed circuit board according to claim 7, wherein said step of forming said wiring layer includes
roughening a surface of a conductor layer in a layered board including an insulating layer and said conductor layer provided over said bending portion and said non-bending portion,
forming a wiring layer on said insulating layer by forming resist for etching in a prescribed region of the surface of said conductor layer and etching said conductor layer excluding said prescribed region,
removing said resist for etching,
forming resist for smoothing in a surface region of said wiring layer in said bending portion,
smoothing the surface region of said wiring layer where said resist for smoothing is not formed, and
removing said resist for smoothing.

12. The method of manufacturing a printed circuit board according to claim 7, wherein said wiring layer has a plurality of wiring layers extending in parallel to one another in said bending portion, and
said step of forming said wiring layer includes roughening a surface region of said plurality of wiring layers in said bending portion excluding the surfaces of said wiring layers facing one another.
